(19) United States
(12) Patent Application Publication
(10) Pub. No.: US 2024/0258459 A1
(43) Pub. Date: Aug. 1, 2024

(54) DISPLAY DEVICE AND PRODUCTION METHOD FOR DISPLAY DEVICE

(71) Applicant: Sharp Display Technology Corporation, Kameyama City, Mie (JP)

(72) Inventors: Sentaro KIDA, Kameyama City, Mie (JP); Yasushi ASAOKA, Kameyama City, Mie (JP); Takahiro ADACHI, Kameyama City, Mie (JP)

(21) Appl. No.: 18/561,658

(22) PCT Filed: Jun. 30, 2021
(86) PCT No.: PCT/JP2021/024872

§ 371 Date: Nov. 16, 2023

(51) Int. Cl. H01L 33/24; H01L 25/075; H01L 33/14

(52) U.S. Cl. CPC H01L 33/24; H01L 25/0753; H01L 33/14

(57) ABSTRACT

A display device includes a function layer including a body portion positioned in a light-emitting region and an edge portion positioned in a non-light-emitting region, and a bank formed in the non-light-emitting region and including an inner wall surface that is a surface on a side of the light-emitting region. The edge portion includes an overhanging portion including a portion having a thickness larger than a thickness of the body portion, and the overhanging portion is formed on the bank.

### TECHNICAL FIELD

The disclosure relates to a display device and a method for manufacturing the display device.

### BACKGROUND ART

Examples of the method for manufacturing the display device include techniques disclosed in PTLS 1 and 2. Examples of the display device include organic light-emitting diode (OLED) display devices and quantum dot light-emitting diode (QLED) display devices. PTLS 1 and 2 disclose that a light-emitting layer (function layer) is formed by applying an organic material ink using a wet application method or the like.

### CITATION LIST

### Patent Literature

PTL 1: JP 2011-60435 A
PTL 2: JP 2011-60518 A

### SUMMARY

### Technical Problem

As a method for forming a function layer of a display device, lift-off has attracted attention. Lift-off is a method including the following (Step A) to (Step C).

(Step A) A mold called a template is formed on a substrate with use of a certain material (it does not matter whether or not it has a patterning property).

(Step B) After Step A, a material desired to be patterned (i.e., a material of a function layer) is deposited on a part or the whole of the template.

(Step C) After Step B, a part or the whole of the template is removed, and an unnecessary portion is removed from the film of the material desired to be patterned to leave a necessary portion.

By forming the function layer by lift-off, the function layer that is highly fine can be easily formed as compared with the case of forming the function layer by a wet application method or the like.

When the function layer is formed by a wet application method or the like, a bank positioned outside a light-emitting region is usually liquid-repellent, and therefore adhesion between an edge portion of the function layer and the bank is prone to be insufficient. When the function layer is formed by lift-off, it is not necessary for the bank positioned outside the light-emitting region to be liquid-repellent, and therefore the edge portion of the function layer and the bank can be sufficiently brought into close contact with each other.

On the other hand, the thickness of the light-emitting layer as an example of the function layer is usually equal to or less than 40 nm, and the thickness of a carrier transport layer as another example of the function layer is usually equal to or less than 80 nm; thus, the function layer is very thin. Therefore, even when the function layer is formed by lift-off, there is a possibility that the edge portion of the function layer is chipped or the function layer is peeled off from the edge portion of the function layer as a starting point.

### Solution to Problem

A display device according to one aspect of the disclosure includes a function layer including a body portion positioned in a light-emitting region and an edge portion positioned in a non-light-emitting region; and a bank formed in the non-light-emitting region and including an inner wall surface that is a surface on a side of the light-emitting region. The edge portion includes an overhanging portion including a portion having a thickness larger than a thickness of the body portion, and the overhanging portion is formed on the bank.

A method for manufacturing a display device according to one aspect of the disclosure includes forming a function layer including a body portion positioned in a light-emitting region and an edge portion positioned in a non-light-emitting region. In the forming the function layer, an overhanging portion including a portion having a thickness larger than a thickness of the body portion is formed in the edge portion.

### Advantageous Effects of Disclosure

According to one aspect of the disclosure, it is possible to reduce the possibility of chipping or peeling off of the function layer.

### BRIEF DESCRIPTION OF DRAWINGS

FIG. 1 is a view illustrating a method for manufacturing a light-emitting element and a display device according to a first embodiment of the disclosure.

FIG. 2 is a view illustrating the method for manufacturing the light-emitting element and the display device according to the first embodiment of the disclosure.

FIG. 3 is a view illustrating the method for manufacturing the light-emitting element and the display device according to the first embodiment of the disclosure.

FIG. 4 is a view for comparing an edge portion of a light-emitting layer according to a comparative example with an edge portion according to the first embodiment of the disclosure.

FIG. 5 is a view illustrating examples of a combination of a shape of an overhanging portion and a shape of a photoresist that comes in contact with the overhanging portion in a fifth step.

FIG. 6 is a view for comparing a structure around the edge portion in the light-emitting layer according to the first embodiment of the disclosure with a structure of a light-emitting layer formed by an ink-jet method.

FIG. 7 is a view illustrating other examples of the overhanging portion.

FIG. 8 is a view illustrating a configuration example of the overhanging portion.

FIG. 9 is a view illustrating a configuration example of the overhanging portion.

FIG. 10 is a view illustrating a configuration example of the overhanging portion.

FIG. 11 is a view illustrating a configuration example of the overhanging portion.

FIG. 12 is a view illustrating a light-emitting element, a display device, and a method for manufacturing them, according to a second embodiment of the disclosure.

FIG. 13 is a view illustrating a light-emitting element, a display device, and a method for manufacturing them, according to a modification of the second embodiment of the disclosure.

FIG. 14 is a view illustrating modifications of the overhanging portion.

FIG. 15 is a view illustrating a display device and a method for manufacturing the display device according to a third embodiment of the disclosure.

FIG. 16 is a view illustrating a display device and a method for manufacturing the display device according to a fourth embodiment of the disclosure.

FIG. 17 is a view illustrating a display device and a method for manufacturing the display device according to a first modification of the fourth embodiment of the disclosure.

FIG. 18 is a view illustrating a display device and a method for manufacturing the display device according to a second modification of the fourth embodiment of the disclosure.

FIG. 19 is a view illustrating an arrangement example of a plurality of light-emitting elements in a display device according to a fifth embodiment of the disclosure.

FIG. 20 is a view illustrating an arrangement example of the plurality of light-emitting elements in the display device according to the fifth embodiment of the disclosure.

FIG. 21 is a view illustrating an arrangement example of the plurality of light-emitting elements in the display device according to the fifth embodiment of the disclosure.

FIG. 22 is a view illustrating an arrangement example of the plurality of light-emitting elements in the display device according to the fifth embodiment of the disclosure.

### DESCRIPTION OF EMBODIMENTS

Embodiments of the disclosure will be described below. Note that, for convenience of description, members having the same functions as the members described earlier may be denoted by the same reference numerals and signs, and the description thereof will not be repeated.

### First Embodiment

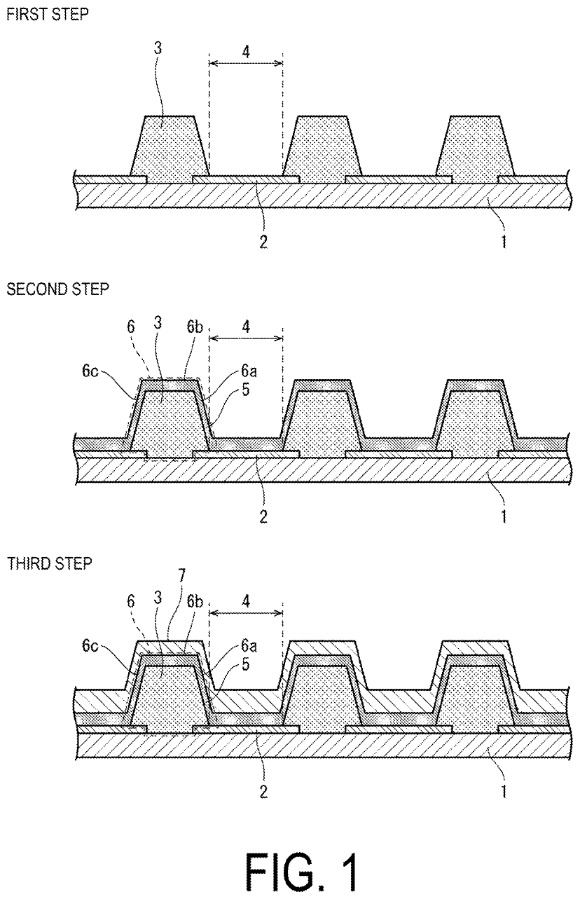

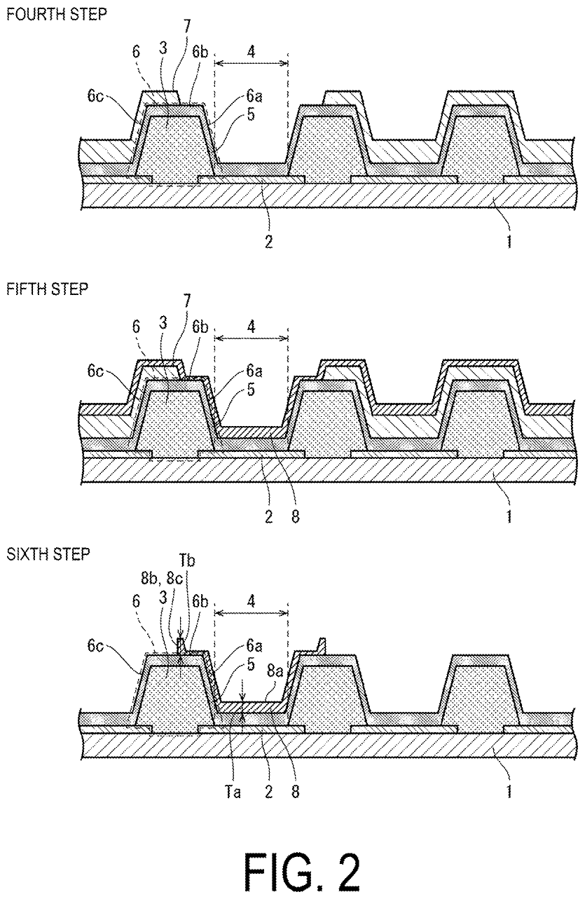

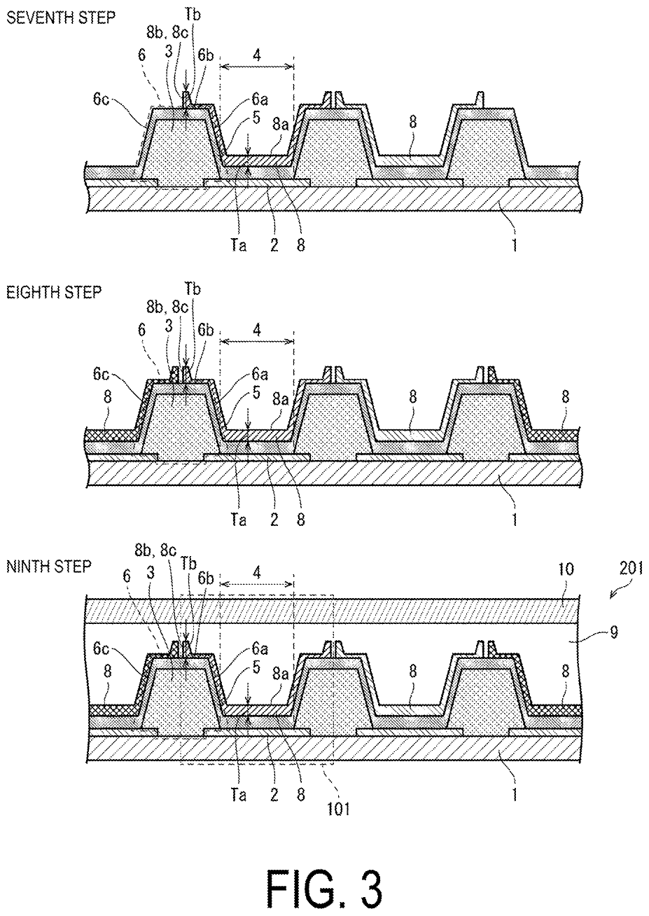

FIGS. 1 to 3 are views illustrating a method for manufacturing a light-emitting element 101 and a display device 201 according to the present embodiment. The method for manufacturing the light-emitting element 101 and the display device 201 according to the present embodiment is roughly divided into a first step to a ninth step. The first step to the third step are illustrated in FIG. 1, the fourth step to the sixth step are illustrated in FIG. 2, and the seventh step to the ninth step are illustrated in FIG. 3. An example of each light-emitting element according to each embodiment is indicated by being surrounded by a broken line in the corresponding drawing, but this is merely an interpretation example, and does not exclude light-emitting elements having a slight excess or deficiency from the illustrated components.

In the first step, an edge cover 3 is formed on a substrate 1 on which a first electrode 2 is formed. The edge cover 3 is formed covering an end portion of the first electrode 2. A plurality of the edge covers 3 may each be formed in an island shape. The edge cover 3 defines, as a light-emitting region 4, a region of the first electrode 2 from a portion where the edge cover 3 is not formed and above. On the other hand, a region other than the light-emitting region 4 is a non-light-emitting region, and the edge cover 3 is formed in at least a part of the non-light-emitting region.

In the second step, a first carrier transport layer 5 is formed on the first electrode 2 and on the edge cover 3. When the first electrode 2 is an anode, the first carrier transport layer 5 is a hole transport layer that transports holes to a light-emitting layer 8. When the first electrode 2 is a cathode, the first carrier transport layer 5 is an electron transport layer that transports electrons to the light-emitting layer 8. Examples of a method for forming the first carrier transport layer 5 include an application method and a vapor deposition method.

Examples of the material of the hole transport layer include NiO, MgNiO, MoOₓ (x is any positive number), CuI, CuSCN, Cu₂O, CoO, Cr₂O₃, TiO₂, CuAlS₂, PEDOT:PSS, TFB, p-TPD, PVK, and TAPC. Examples of the material of the electron transport layer include ZnO, ZnS, ZrO, LiZnO, MgZnO, AlZnO, and TiO₂. Furthermore, examples of the material of the hole transport layer (photosensitive) include OTPD, QUPD, and X-F6-TAPC. Each of the hole transport layer and the electron transport layer may have a layered structure such as a layered structure of MgZnO and ZnO or a layered structure of PEDOT:PSS and TFB. The thickness of the first carrier transport layer 5 is, for example, equal to or less than 80 nm.

Here, a bank 6 is defined. The bank 6 is a wall-shaped member including the edge cover 3 and a member formed above the edge cover 3 at the time point of forming the light-emitting layer 8. The member formed above the edge cover 3 at the time point of forming the light-emitting layer 8 may be placed directly on the surface of the edge cover 3, or may be placed (indirectly) over the surface of the edge cover 3 in a state where another member is interposed between itself and the surface of the edge cover 3. When there is no member formed above the edge cover 3 at the time point of forming the light-emitting layer 8, the bank 6 is composed of the edge cover 3. In FIGS. 1 to 3, the bank 6 is defined as a wall-shaped member including the edge cover 3 and a portion of the first carrier transport layer 5 placed on the edge cover 3.

The bank 6 has a table shape. In other words, the bank 6 includes an inner wall surface 6a, an upper surface 6b, and an outer wall surface 6c. The inner wall surface 6a is a surface on the light-emitting region 4 side, and the outer wall surface 6c is a surface on an opposite side to the light-emitting region 4. Almost the whole inner wall surface 6a is formed outside the light-emitting region 4, but depending on the shape of the member formed above the edge cover 3 at the time point of forming the light-emitting layer 8 described above, a slight part of the inner wall surface 6a can be formed inside the light-emitting region 4. The above indicates that the bank 6 includes at least a part of the inner wall surface 6a outside the light-emitting region 4, includes the upper surface 6b outside the inner wall surface 6a with respect to the light-emitting region 4, and includes the outer wall surface 6c outside the inner wall surface 6a and the upper surface 6b with respect to the light-emitting region 4. In a case of not having discussion based on the concept of “inner” and “outer” of the inner wall surface 6a and the outer wall surface 6c, it is possible to simply interpret the inner wall surface 6a as a wall surface. Forming the bank 6 as described above in a step before the second step corresponds to a step of forming at least a part of the inner wall surface 6a outside the light-emitting region 4.

In the third step, a photoresist 7 is formed on the first carrier transport layer 5. The third step is a step of forming the photoresist 7. Examples of the material of the photoresist 7 include an acrylic material, a novolak material, a rubber material, a styrene material, and an epoxy material.

In the fourth step, a part of the photoresist 7 is exposed, the photoresist 7 is developed, and a part of the photoresist 7 is removed. The fourth step is a step of forming a template by exposing and developing the photoresist 7. Specifically, a portion of the photoresist 7 on the first electrode 2, on the inner wall surface 6a, and on a part of the upper surface 6b (a certain area from the boundary between the inner wall surface 6a and the upper surface 6b) is removed. Examples of a developer required for developing the photoresist 7 include KOH, NaOH, and other inorganic alkalis, TMAH and other organic alkalis, PGME, PGMEA, Acetone, NMP, DMSO, IPA, and EtOH.

In the fifth step and the sixth step, the light-emitting layer 8 is formed using, as a template, the photoresist 7 remaining after the fourth step. The light-emitting layer 8 is an example of a function layer.

In the fifth step, the light-emitting layer 8 is formed on the first carrier transport layer 5 in the portion where the photoresist 7 is removed in the fourth step, and on the photoresist 7 in the other portions. The fifth step is a step of applying the light-emitting layer 8 as a function layer. Although the name of the step is “step of applying”, the step is not limited to application by an application method, and a technique of forming the function layer by application by a vapor deposition method or the like is also included.

The light-emitting layer 8 may be a light-emitting layer of an OLED display device or a light-emitting layer of a QLED display device. The light-emitting layer of the QLED display device includes a quantum dot, and examples of the structure of the quantum dot include a core structure, a core/shell structure, and a core/first shell/second shell structure. The shell may be provided around the core. The first shell and the second shell may be provided around the core in this order from the core. In the core/shell structure, the ratio of elements of the shell may be continuously changed.

Examples of the core are as follows.
Unitary system: Si and C
Binary system: CdSe, CdS, CdTe, InP, GaP, InN, ZnSe, ZnS, and ZnTe
Ternary system: CdSeTe, GaInP, and ZnSeTe
Quaternary system: AIGS

Examples of the shell (including the first shell and the second shell) are as follows.
Binary system: CdS, CdTe, CdSe, ZnS, ZnSe, and ZnTe
Ternary system: CdSSe, CdTeSe, CdSTe, ZnSSe, ZnSTe, ZnTeSe, and AlP

In the sixth step, the portion of the photoresist 7 that has not been removed in the fourth step is removed. The sixth step is a step of lifting off the photoresist 7 as a template to form the light-emitting layer 8 as a function layer in a predetermined region. The “predetermined region” includes a part of the non-light-emitting region and the light-emitting region 4 as illustrated in the view of the sixth step in FIG. 2, for example. Removal of the portion of the photoresist 7 not removed in the fourth step may be performed by exposure and development, or may be performed using a solvent.

In the present embodiment, the lift-off can be defined as a method including the following (Step a) to (Step c).

(Step a) A mold called a template is formed over the substrate 1 and the like with the photoresist 7.

(Step b) After Step a, a material desired to be patterned (i.e., the material of the light-emitting layer 8) is deposited on a part or the whole of the template.

(Step c) After Step b, a part or the whole of the template is removed, and an unnecessary portion is removed from the film of the material desired to be patterned to leave a necessary portion.

The light-emitting layer 8 formed through the sixth step includes a body portion 8a and an edge portion 8b. The body portion 8a corresponds to a portion above the first electrode 2 and not above the edge cover 3. In other words, the body portion 8a is positioned in the light-emitting region 4. The edge portion 8b corresponds to a portion positioned outside the inner wall surface 6a with respect to the light-emitting region 4. In the light-emitting layer 8, a thickness Tb, which is the maximum value of the thickness of the edge portion 8b, is larger than a thickness Ta of the body portion 8a. The thickness Ta is, for example, equal to or less than 40 nm. The thickness Tb (the maximum value of the thickness of an overhanging portion 8c) is preferably twice or more the thickness Ta.

The third step to the sixth step described above are steps of forming the light-emitting layer 8 as a function layer.

Note that the thickness of a layer (film) means the size of the layer (film) in the normal direction of the surface on which the layer (film) is formed.

In the seventh step, another light-emitting layer 8 is formed in the same manner as that of the third step to the sixth step. In the eighth step, yet another light-emitting layer 8 is formed in the same manner as that of the third step to the sixth step. In the ninth step, a second carrier transport layer 9 and a second electrode 10 are formed in this order on each light-emitting layer 8. When the second electrode 10 is an anode, the second carrier transport layer 9 is a hole transport layer. When the second electrode 10 is a cathode, the second carrier transport layer 9 is an electron transport layer. The second carrier transport layer 9 and/or the second electrode 10 may be formed collectively for two or more light-emitting layers 8. Through the third step to the eighth step, a plurality of the light-emitting layers 8 are individually formed, and the plurality of light-emitting layers 8 are separately patterned.

Note that as illustrated in FIG. 3, the light-emitting element 101 is formed for each light-emitting layer 8, and the display device 201 includes a plurality of the light-emitting elements 101. In the method for manufacturing the display device 201, it can be said that the plurality of light-emitting layers 8 including the light-emitting layer 8 of the light-emitting element 101 manufactured by the method for manufacturing the light-emitting element 101 are formed, or it can be said that the plurality of light-emitting elements 101 are formed by the method for manufacturing the light-emitting element 101.

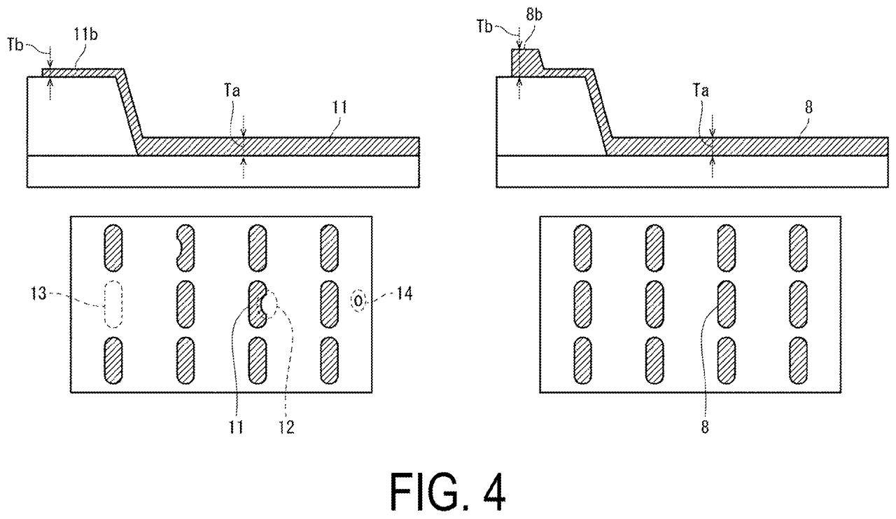

FIG. 4 is a view for comparing an edge portion 11b of a light-emitting layer 11 according to a comparative example with the edge portion 8b according to the present embodiment.

In the edge portion 11b, the thickness Tb is equal to or less than the thickness Ta. In this case, there is a possibility that the edge portion 11b is chipped (see reference sign 12 in FIG. 4) or the light-emitting layer 11 is peeled off from the edge portion 11b as a starting point (see reference sign 13 in FIG. 4). There is also a possibility that a chipped or peeled portion of the light-emitting layer 11 is reattached to an unexpected place (see reference sign 14 in FIG. 4).

In the edge portion 8b, the thickness Tb is larger than the thickness Ta. Therefore, the possibility of chipping or peeling off of the light-emitting layer 8 can be reduced.

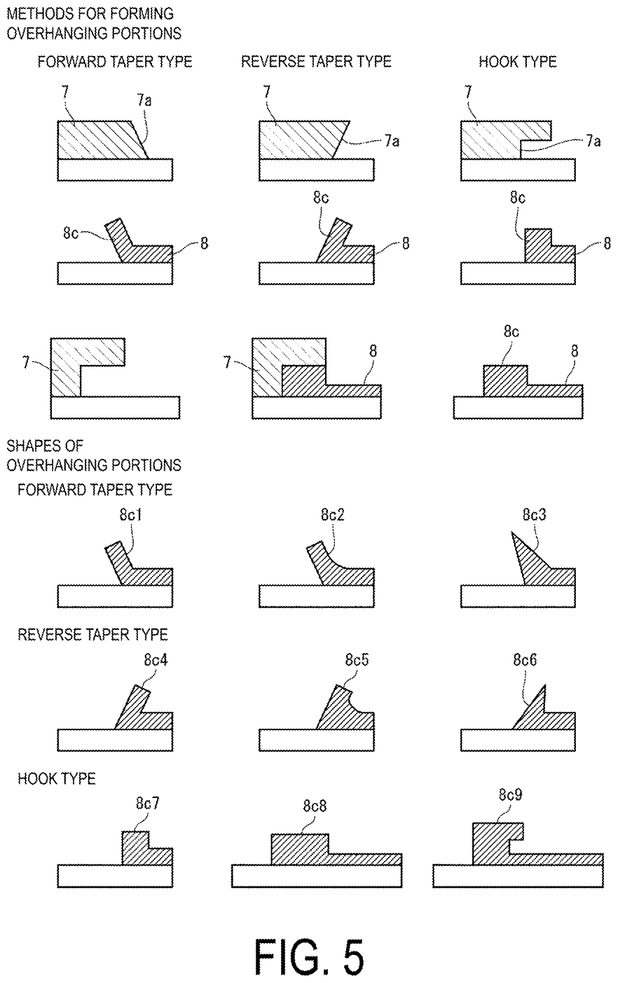

FIG. 5 is a view illustrating examples of a combination of the shape of the overhanging portion 8c and the shape of the photoresist 7 that comes in contact with the overhanging portion 8c in the fifth step.

In order to achieve the thickness Tb larger than the thickness Ta, it is effective to form, in the edge portion 8b, the overhanging portion 8c including the thickest portion (i.e., a portion whose thickness is the thickness Tb larger than the thickness of the body portion 8a) of the edge portion 8b. The overhanging portion 8c may be a thick film portion formed thicker than the body portion 8a, or may have a structure in which an end portion of the edge portion 8b having almost the same thickness as the body portion 8a is blown back.

Examples of the shape of the photoresist 7 that comes in contact with the overhanging portion 8c in the fifth step include a forward taper type, a reverse taper type, and a hook type. The forward taper type includes a tapered shape farther from the light-emitting region 4 at a higher position on a surface 7a that is a contact surface of the photoresist 7 with the overhanging portion 8c. The reverse taper type includes a tapered shape closer to the light-emitting region 4 at a higher position on the surface 7a. The hook type includes a shape in which the surface 7a is bent in the light-emitting region 4 direction at a certain height.

FIG. 5 lists examples of the shape of the edge portion 8b including the transfer shape of the photoresist 7 of the forward taper type, the transfer shape of the photoresist 7 of the reverse taper type, or the transfer shape of the photoresist 7 of the hook type. Specifically, FIG. 5 illustrates overhanging portions 8cl to 8c9 as the overhanging portion 8c that is preferably included in the edge portion 8b. Each of the overhanging portions 8cl to 8c3 includes a transfer shape of the photoresist 7 of the forward taper type. Each of the overhanging portions 8c4 to 8c6 includes a transfer shape of the photoresist 7 of the reverse taper type. Each of the overhanging portions 8c7 to 8c9 includes a transfer shape of the photoresist 7 of the hook type.

The overhanging portion 8c may have a shape including a round portion as in the overhanging portions 8c2 and 8c5. The tip of the overhanging portion 8c may have an acute angle as in the overhanging portions 8c3 and 8c6. The overhanging portion 8c may have a shape including a fold-back as in the overhanging portion 8c9.

Note that it is preferable that the material of the light-emitting layer 8 easily gets wet with respect to the photoresist 7. For this reason, as a measure that can be made on the photoresist 7 side, the following are conceivable: reducing the surface tension of the photoresist 7, not using a liquid-repellent material in the material of the photoresist 7, performing lyophilic treatment (excimer plasma treatment or the like) on the surface of the photoresist 7, and the like. On the other hand, as a measure that can be made on the light-emitting layer 8 side, the following are conceivable: mixing a solvent (quantum dots dispersed with low surface tension, or alcohols), a surfactant, or the like with the material of the light-emitting layer 8.

The overhanging portion 8c of the edge portion 8b is formed with respect to the bank 6. This makes it possible to prevent leakage.

The overhanging portion 8c of the edge portion 8b is formed on the upper surface 6b. This can reduce the possibility of occurrence of a film thickness defect, disconnection, and the like of the light-emitting layer 8.

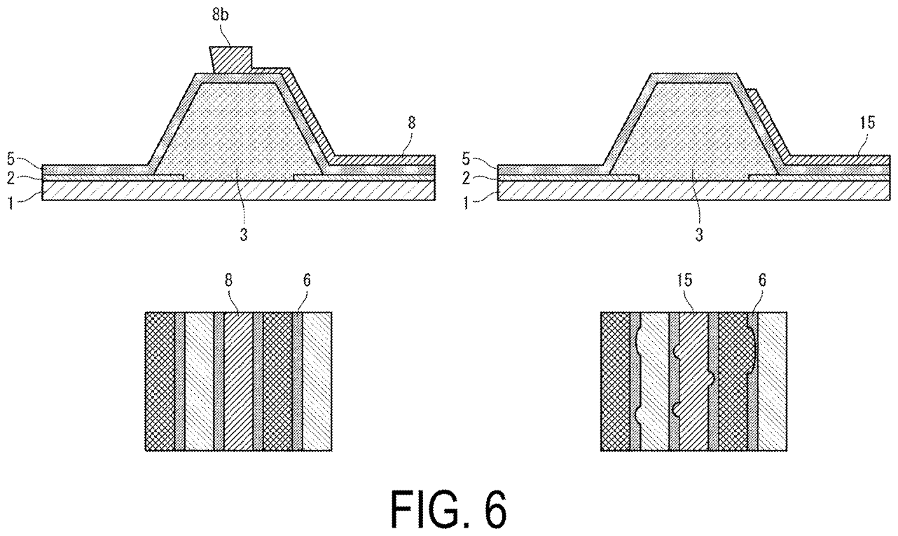

FIG. 6 is a view for comparing the structure around the edge portion 8b in the light-emitting layer 8 with the structure of a light-emitting layer 15 formed by an ink-jet method.

According to FIG. 6, while the transfer shape of the photoresist 7 in the fifth step remains in the edge portion 8b, such a shape does not remain in the light-emitting layer 15.

According to FIG. 6, regarding application unevenness such as the light-emitting layer being put on the bank 6, the application unevenness of the light-emitting layer 15 with respect to the bank 6 tends to be larger than the application unevenness of the light-emitting layer 8 with respect to the bank 6.

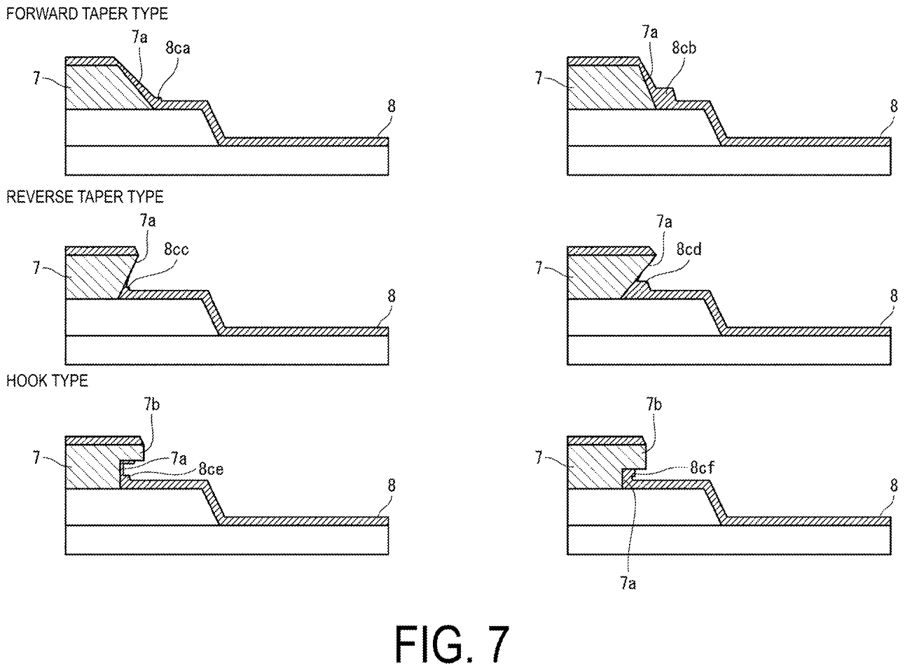

FIG. 7 is a view illustrating overhanging portions 8ca to 8cf as other examples of the overhanging portion 8c.

The larger the size of the overhanging portion 8c is, and the thicker as many portions of the overhanging portion 8c as possible are, the more remarkable the effect of reducing the possibility of chipping or peeling off of the light-emitting layer 8 becomes.

Each of the overhanging portions 8ca and 8cb can be interpreted as a protruding portion (liquid pool) of the material of the light-emitting layer 8, which corresponds to the transfer shape of the photoresist 7 of the forward taper type. The steeper the slope of the surface 7a is, the larger the size of each of the overhanging portions 8ca and 8cb becomes. The size of each of the overhanging portions 8ca and 8cb also depends on the wettability of the material of the light-emitting layer 8 with respect to the photoresist 7, the viscosity and dryness of the material of the light-emitting layer 8, the surface tension of the photoresist 7, and the like.

Each of the overhanging portions 8cc and 8cd can be interpreted as a protruding portion (liquid pool) of the material of the light-emitting layer 8, which corresponds to the transfer shape of the photoresist 7 of the reverse taper type. The steeper the slope of the surface 7a is, the larger the size of each of the overhanging portions 8cc and 8cd becomes. The size of each of the overhanging portions 8cc and 8cd also depends on the wettability of the material of the light-emitting layer 8 with respect to the photoresist 7, the viscosity and dryness of the material of the light-emitting layer 8, the surface tension of the photoresist 7, and the like.

Each of the overhanging portions 8ce and 8cf can be interpreted as a protruding portion (liquid pool) of the material of the light-emitting layer 8, which corresponds to the transfer shape of the photoresist 7 of the hook type. As the bending position of the surface 7a in the light-emitting region 4 direction is, in other words, the lower the lower end of an umbrella portion 7b of the photoresist 7 is, the thicker the whole of each of the overhanging portions 8ce and 8cf can be formed.

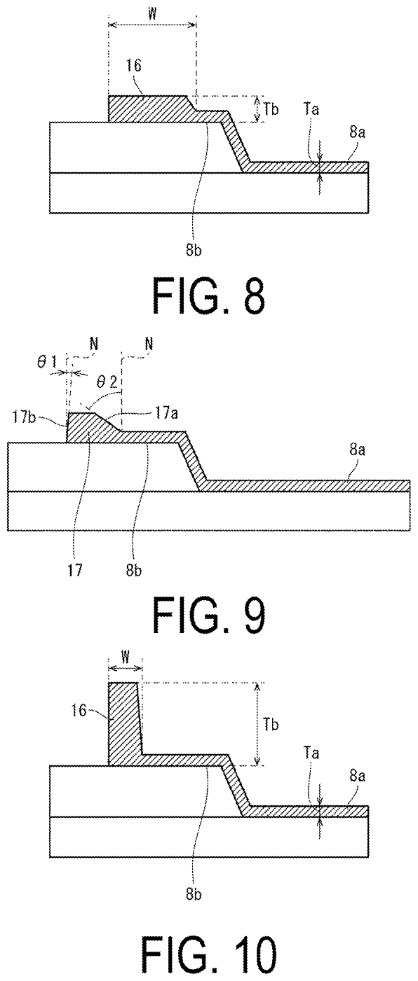

FIG. 8 is a view illustrating a configuration example of an overhanging portion 16. The overhanging portion 16 is a thick film portion in the edge portion 8b, which is formed thicker than the body portion 8a, of the overhanging portion 8c.

In FIG. 8, the width of the overhanging portion 16 is a width W. The maximum value of the thickness of the overhanging portion 16 is the thickness Tb, and the thickness of the body portion 8a is the thickness Ta. Note that the width of the overhanging portion 16 means the size of the overhanging portion 16 along the surface on which the overhanging portion 16 is formed.

The edge portion 8b includes the overhanging portion 16 formed thicker than the body portion 8a (i.e., the relationship of Ta<Tb is satisfied), and the width W of the overhanging portion 16 is preferably larger than the thickness Ta of the body portion 8a.

The width W of the overhanging portion 16 is preferably larger than the thickness Tb. Due to thus, the stress acting on the overhanging portion 16 in the direction where the overhanging portion 16 is peeled off is alleviated, or the durability of the overhanging portion 16 against the stress is increased, and therefore the overhanging portion 16 becomes less prone to be peeled off. A layer above the overhanging portion 16 is less prone to be affected by the shape of the overhanging portion 16 itself. For example, when an external force is applied to the overhanging portion 16, it is possible to suppress separation of only the overhanging portion 16 from the light-emitting layer 8. Furthermore, this makes it possible to maintain flatness when a layer above the light-emitting layer 8 is formed, and therefore it is possible to reduce the possibility of occurrence of disconnection or the like.

FIG. 9 is a view illustrating a configuration example of an overhanging portion 17. The overhanging portion 17 is a thick film portion in the edge portion 8b, which is formed thicker than the body portion 8a, of the overhanging portion 8c.

The edge portion 8b includes the overhanging portion 17 formed thicker than the body portion 8a. FIG. 9 corresponds to a cross-sectional view of the light-emitting element 101. When an inclination angle of a side wall 17b of the overhanging portion 17 on an opposite side to the light-emitting region 4 with respect to a normal direction N of the surface on which the overhanging portion 17 is formed is θ1 and an inclination angle of a side wall 17a of the overhanging portion 17 on the light-emitting region 4 side with respect to the normal direction N is θ2, θ1<θ2 is preferably satisfied. This can reduce the possibility that the overhanging portion 17 becomes a starting point of peeling off of the light-emitting layer 8. Note that θ1 and θ2 are assumed to be angles (0° or more and less than 90°) such that the size of the upper end of the overhanging portion 17 decreases as the angles increase.

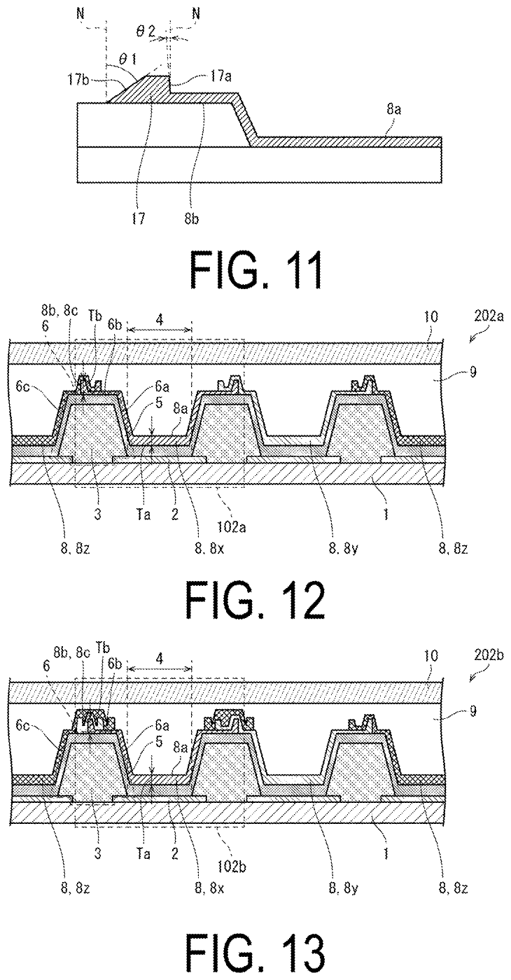

Note that as illustrated in FIGS. 10 and 11, the thickness Tb may be larger than the width W in the overhanging portion 16, or θ2≤θ1 may be satisfied in the overhanging portion 17.

The method for manufacturing the light-emitting element 101 can be interpreted as a method for manufacturing the light-emitting element 101 including the bank 6 including at least a part of the wall surface (the inner wall surface 6a) outside the light-emitting region 4 and at least one function layer (the light-emitting layer 8) including the body portion 8a positioned in the light-emitting region 4 and the edge portion 8b positioned outside the wall surface with respect to the light-emitting region 4, and can be interpreted as a method for making the thickness Tb, which is the maximum value of the thickness of the edge portion 8b, larger than the thickness Ta of the body portion 8a.

The method for manufacturing the display device 201 can be interpreted as a method for forming a plurality of the light-emitting elements 101 by the method for manufacturing the light-emitting element 101.

### Second Embodiment

FIG. 12 is a view illustrating a light-emitting element 102a, the display device 202a, and a method for manufacturing them, according to the present embodiment. FIG. 13 is a view illustrating a light-emitting element 102b, a display device 202b, and a method for manufacturing them, according to a modification of the present embodiment. In a display device including a plurality of the light-emitting regions 4, for example, each of the light-emitting regions 4 is included in a different pixel. FIGS. 12 and 13 illustrate flattening performed by the second carrier transport layer 9, but the second carrier transport layer 9 may be formed reflecting the shape of a layer below the second carrier transport layer 9.

The display device 202a illustrated in FIG. 12 includes a plurality of the light-emitting elements 102a, and the edge portions 8b of the light-emitting layers 8 of the plurality of light-emitting elements 102a overlap each other. This can reduce the possibility of chipping or peeling off of the light-emitting layer 8 including the lower edge portion 8b in particular. FIG. 12 illustrates an example in which the edge portions 8b of the two light-emitting layers 8 overlap each other.

The display device 202b illustrated in FIG. 13 includes a plurality of the light-emitting elements 102b, and the edge portions 8b of the light-emitting layers 8 of the plurality of light-emitting elements 102b overlap each other. This can reduce the possibility of chipping or peeling off of the light-emitting layer 8 including the lower edge portion 8b in particular. FIG. 13 illustrates an example in which the edge portions 8b of three light-emitting layers 8 overlap each other in addition to an example in which the edge portions 8b of two light-emitting layers 8 overlap each other.

The light-emitting layer 8 formed in the third step to the sixth step (see FIGS. 1 and 2) is referred to as a light-emitting layer (first function layer) 8x, the light-emitting layer 8 formed in the seventh step (see FIG. 3) is referred to as a light-emitting layer (second function layer) 8y, and the light-emitting layer 8 formed in the eighth step (see FIG. 3) is referred to as a light-emitting layer (third function layer) 8z. At this time, each of the display devices 202a and 202b can be manufactured by a combination of three steps of overlapping the edge portion 8b of the light-emitting layer 8y with the edge portion 8b of the light-emitting layer 8x, overlapping the edge portion 8b of the light-emitting layer 8z with the edge portion 8b of the light-emitting layer 8x, and overlapping the edge portion 8b of the light-emitting layer 8z with the edge portion 8b of the light-emitting layer 8y. Here, the step of overlapping the edge portion 8b formed in the light-emitting layer 8x and the edge portion 8b formed in the light-emitting layer 8z is included.

Note that examples of the light-emitting layers 8x to 8z include a red light-emitting layer that emits red light, a green light-emitting layer that emits green light, and a blue light-emitting layer that emits blue light. Which of the light-emitting layers 8x to 8z may be the red light-emitting layer, which of the light-emitting layers 8x to 8z may be the green light-emitting layer, and which of the light-emitting layers 8x to 8z may be the blue light-emitting layer.

Note that as illustrated in FIG. 12, the light-emitting element 102a is formed for each light-emitting layer 8, and the display device 202a includes the plurality of light-emitting elements 102a. As illustrated in FIG. 13, the light-emitting element 102b is formed for each light-emitting layer 8, and the display device 202b includes the plurality of light-emitting elements 102b.

Regarding FIG. 13, the overhanging portions 8c may be formed at different locations in the light-emitting layers 8x to 8z, but may be formed at the same location. This makes it less prone to be peeled off. The light-emitting layer 8x needs not be formed on the bank 6 between the light-emitting layer 8y and the light-emitting layer 8z. When the light-emitting layer 8x is formed on the bank 6 between the light-emitting layer 8y and the light-emitting layer 8z, the film thickness on the bank 6 increases, and light emission and leakage on the bank 6 can be suppressed.

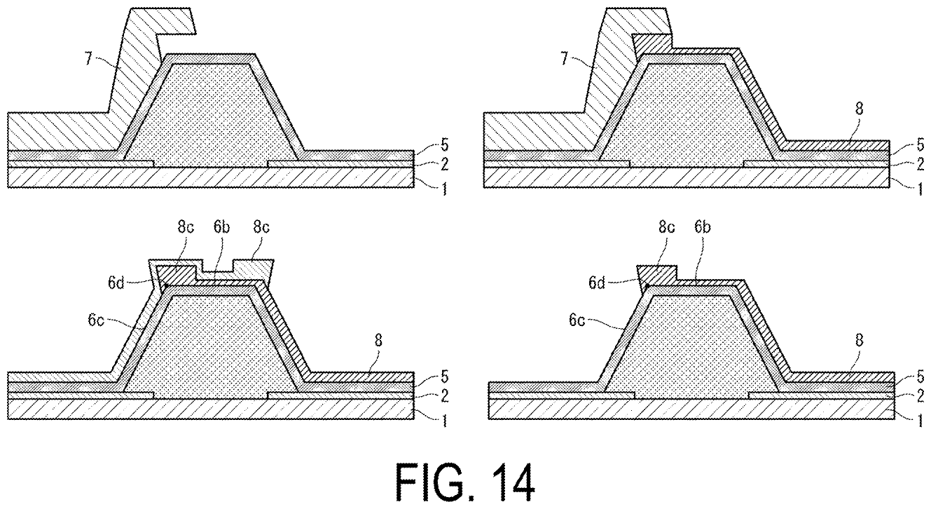

FIG. 14 is a view illustrating a modification of the overhanging portion 8c.

According to FIG. 14, the overhanging portion 8c may be formed at a boundary 6d between the upper surface 6b and the outer wall surface 6c. This can reduce the possibility that due to cutting of the edge portion 8b around the boundary 6d, leakage occurs and the light emission efficiency decreases.

### Third Embodiment

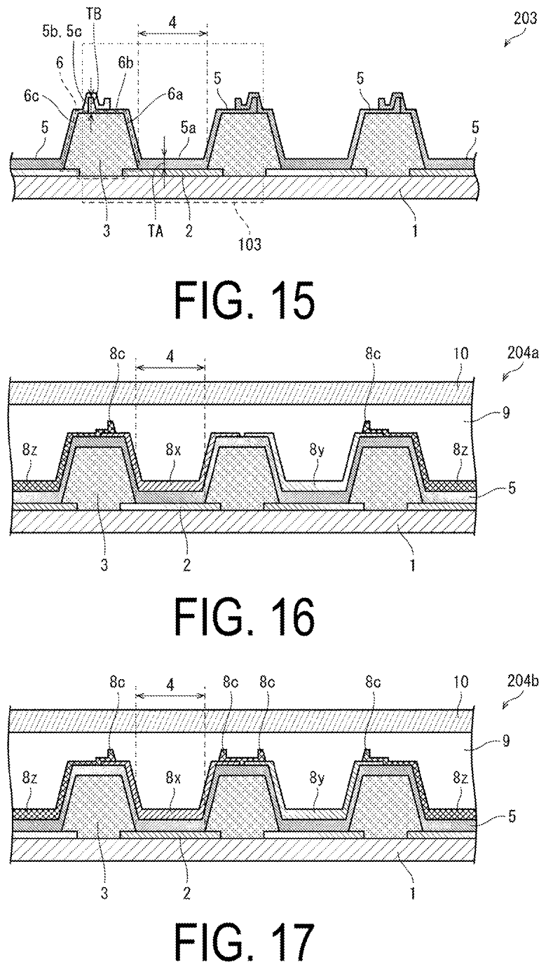

FIG. 15 is a view illustrating a display device 203 and a method for manufacturing the display device 203 according to the present embodiment. Note that in FIG. 15, illustration of layers above the first carrier transport layer 5 are omitted for the sake of brevity of the illustration.

In FIG. 15, the first carrier transport layer 5 is an example of a function layer. That is, the first carrier transport layer 5 includes a body portion 5a positioned in the light-emitting region 4 and an edge portion 5b positioned outside the inner wall surface 6a with respect to the light-emitting region 4. A thickness TB, which is the maximum value of the thickness of the edge portion 5b, is larger than a thickness TA of the body portion 5a. The edge portion 5b includes an overhanging portion 5c including a portion having the thickness TB larger than the thickness TA of the body portion 5a.

In FIG. 15, a plurality of the first carrier transport layers 5 are individually formed by forming the first carrier transport layer 5 in units of one light-emitting element 103. Due to this, the first carrier transport layer 5 suitable for each light-emitting element 103 can be formed; thus, the light-emitting element 103 and the display device 203 having high light emission efficiency can be manufactured.

Both the light-emitting layer 8 and the first carrier transport layer 5 serving as function layers may be formed using a common template. Specifically, the first carrier transport layer 5 may be formed in addition to the light-emitting layer 8 using, as a template, the photoresist 7 remaining in the fourth step (see FIG. 2). This can reduce the number of times of forming the template, and therefore it is possible to reduce the manufacturing man-hours of the light-emitting element and eventually the display device.

The present embodiment may be applied to the second carrier transport layer 9 instead of the first carrier transport layer 5. The present embodiment may be applied to both the first carrier transport layer 5 and the second carrier transport layer 9.

### Fourth Embodiment

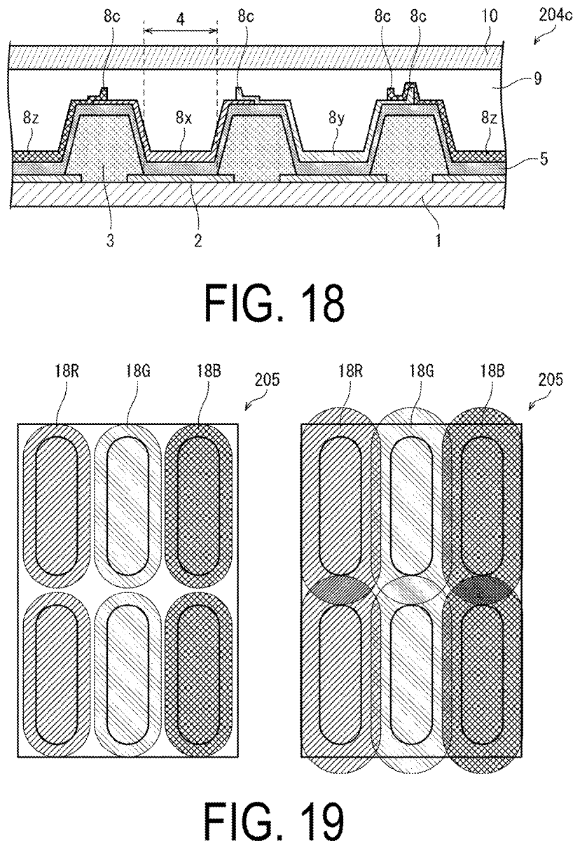

FIG. 16 is a view illustrating a display device 204a and a method for manufacturing a display device 204a, according to the present embodiment. FIG. 17 is a view illustrating a display device 204b and a method for manufacturing a display device 204b, according to the first modification of the present embodiment. FIG. 18 is a view illustrating a display device 204c and a method for manufacturing a display device 204c, according to the second modification of the present embodiment.

As illustrated in FIG. 16, as a plurality of function layers, the light-emitting layer (first function layer) 8x, the light-emitting layer (second function layer) 8y, and the light-emitting layer (third function layer) 8z may be formed in this order, and the overhanging portion 8c formed in the light-emitting layer 8z may be overlapped with at least one of the end portion of the light-emitting layer 8x and the end portion of the light-emitting layer 8y. In FIG. 16, the two overhanging portions 8c are overlapped with the end portion of the light-emitting layer 8x and the end portion of the light-emitting layer 8y, respectively, but one overhanging portion 8c may be overlapped with the end portion of the light-emitting layer 8x and/or the end portion of the light-emitting layer 8y. This can reduce unevenness in the film thickness of each layer formed on the plurality of light-emitting layers 8.

As illustrated in FIG. 17, the light-emitting layer 8z including the overhanging portion 8c overlapping the end portion of the light-emitting layer 8x and the end portion of the light-emitting layer 8y adjacent to each other may be formed. When this overhanging portion 8c is overlapped with the end portion of the light-emitting layer 8x and the end portion of the light-emitting layer 8y, it is possible to reduce the possibility of chipping or peeling off of the light-emitting layers 8x and 8y under the overhanging portion 8c of the light-emitting layer 8z.

As illustrated in FIG. 18, the overhanging portion 8c formed in the light-emitting layer 8y may be overlapped with the end portion of the light-emitting layer 8x adjacent to the light-emitting layer 8y. This can reduce the possibility of chipping or peeling off of the light-emitting layer 8y.

In the present embodiment, the edge portion 8b of the light-emitting layer 8z may cover the end portion until then, and the edge portion 8b may be thickened, whereby a film thickness defect of a charge transport layer of the upper layer and a layer above the charge transport layer can be reduced. The light-emitting layer 8z may be left between the light-emitting layer 8x and the light-emitting layer 8y, whereby the portion covered in the above becomes less prone to be peeled off. It may be performed on and after the light-emitting layer 8y described above.

In FIG. 16, by thickening only the light-emitting layer 8z, the charge transport layer of the upper layer and the like can be applied and formed without film thickness unevenness. In FIG. 17, since only the light-emitting layer 8z is thickened and each end portion between the light-emitting layer 8x and the light-emitting layer 8y is covered with the light-emitting layer 8z so that the edge portion 8b is thick, the occurrence of chipping is suppressed in addition to the above. FIG. 18 can be interpreted as the light-emitting layer 8y version of FIG. 17, and the occurrence of chipping of the light-emitting layer 8y is suppressed in addition to the above.

### Fifth Embodiment

FIGS. 19 to 22 are views illustrating arrangement examples of a plurality of light-emitting elements in a display device 205 according to the present embodiment.

The display device 205 includes, as a plurality of light-emitting layers, a red light-emitting layer 18R that emits red light, a green light-emitting layer 18G that emits green light, and a blue light-emitting layer 18B that emits blue light.

As illustrated in FIG. 19, the place where the red light-emitting layer 18R, the green light-emitting layer 18G, and the blue light-emitting layer 18B are left may be isolated or an overlap between them (there may be such an overlap for only the same color, only different colors, and for both the same color and different colors).

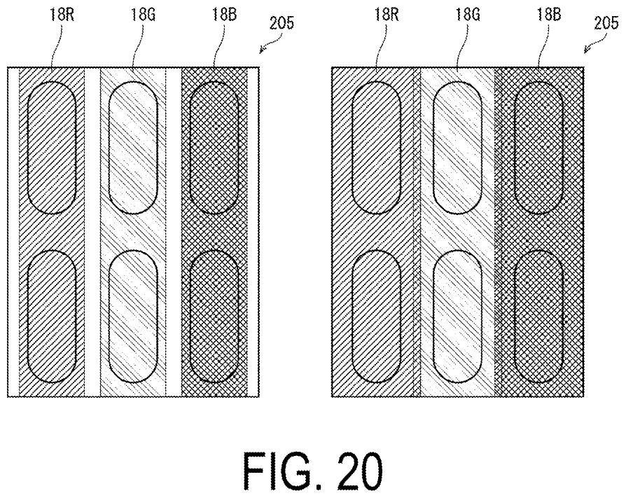

As illustrated in FIG. 20, the red light-emitting layer 18R, the green light-emitting layer 18G, and the blue light-emitting layer 18B may each have a line shape (may overlap each other laterally). In this case, since the area of one function layer becomes widened, peeling off of the function layer becomes less prone to occur.

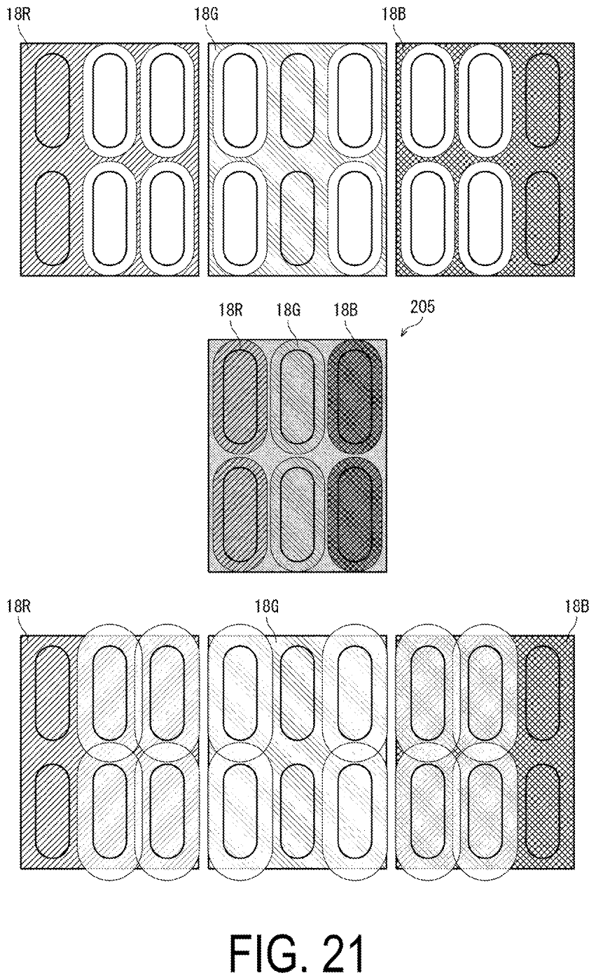

As illustrated in FIG. 21, the red light-emitting layer 18R, the green light-emitting layer 18G, and the blue light-emitting layer 18B may have a continuous pattern (e.g., a portion where a light-emitting layer is not formed at the time of forming the light-emitting layer of the first color may be isolated or continuous. There may be an overlap of such portions for only the same color, for only different colors, and for both the same color and different colors). Due to this, since there are many layered portions and are continuous, peeling off is further less prone to occur. Since the light-emitting layers are layered between pixels and the resistance increases, leakage from a portion between the pixels can be suppressed.

A plurality of the red light-emitting layers 18R may be continuously formed. This widens the area of the series of red light-emitting layers 18R as an object; thus, peeling off of the red light-emitting layers 18R becomes less prone to occur. The same applies to a plurality of the green light-emitting layers 18G and a plurality of the blue light-emitting layers 18B.

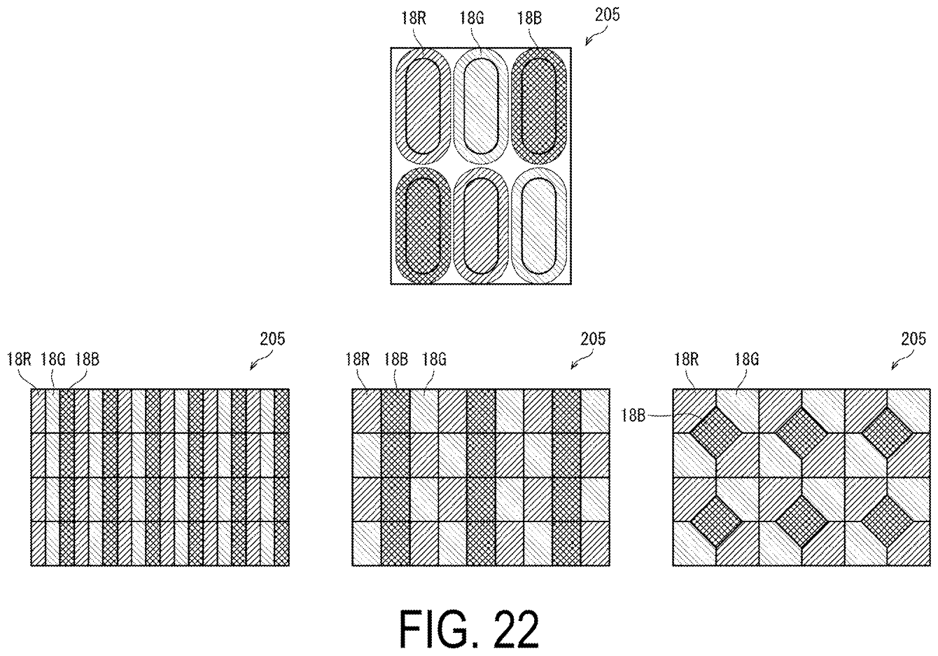

In addition, various arrangements such as various patterns illustrated in FIG. 22 can be exemplified.

### Supplement

A display device according to a first aspect of the disclosure includes a function layer including a body portion positioned in a light-emitting region and an edge portion positioned in a non-light-emitting region; and a bank formed in the non-light-emitting region and including an inner wall surface that is a surface on a side of the light-emitting region. The edge portion includes an overhanging portion including a portion having a thickness larger than a thickness of the body portion, and the overhanging portion is formed on the bank.

In a display device according to a second aspect of the disclosure, in the first aspect, the bank is formed in a table shape including an upper surface.

In a display device according to a third aspect of the disclosure, in the second aspect, the bank includes an outer wall surface positioned outside the inner wall surface with respect to the light-emitting region, and the overhanging portion is formed at a boundary between the upper surface and the outer wall surface.

In a display device according to a fourth aspect of the disclosure, in any of the first to third aspects, a maximum value of a thickness of the overhanging portion is twice or more the thickness of the body portion.

In a display device according to a fifth aspect of the disclosure, in any of the first to fourth aspects, a width of the overhanging portion is larger than the thickness of the body portion.

In a display device according to a sixth aspect of the disclosure, in any of the first to fifth aspects, a width of the overhanging portion is larger than a maximum value of a thickness of the overhanging portion.

In a display device according to a seventh aspect of the disclosure, in any of the first to sixth aspects, when an inclination angle of a side wall of the overhanging portion on an opposite side to the light-emitting region with respect to a normal direction of a surface on which the overhanging portion is formed is θ1 and an inclination angle of a side wall of the overhanging portion on the side of the light-emitting region with respect to the normal direction is θ2, θ1<θ2 is satisfied.

A display device according to an eighth aspect of the disclosure, in any of the first to seventh aspects, includes a plurality of the function layers. The function layers include a first function layer, a second function layer, and a third function layer.

In a display device according to a ninth aspect of the disclosure, in the eighth aspect, the first function layer, the second function layer, and the third function layer are light-emitting layers configured to emit lights in different colors of red, green, and blue.

In a display device according to a tenth aspect of the disclosure, in the eighth or ninth aspect, the overhanging portion of the third function layer overlaps at least one of an end portion of the first function layer and an end portion of the second function layer.

In a display device according to an 11th aspect of the disclosure, in the tenth aspect, the overhanging portion of the third function layer overlaps the end portion of the first function layer and the end portion of the second function layer adjacent to each other.

In a display device according to a 12th aspect of the disclosure, in any of the eighth to 11th aspects, the overhanging portion of the second function layer overlaps an end portion of the first function layer adjacent to the second function layer.

A display device according to a 13th aspect of the disclosure, in any of the first to seventh aspects, includes a plurality of the function layers. The function layers are carrier transport layers, and the plurality of function layers are formed for each pixel.

In a display device according to a 14th aspect of the disclosure, in any of the eighth to 13th aspects, the plurality of function layers are each formed in a line shape.

In a display device according to a 15th aspect of the disclosure, in any of the eighth to 13th aspects, the function layers are continuously formed.

A method for manufacturing a display device, according to a 16th aspect of the disclosure, includes forming a function layer including a body portion positioned in a light-emitting region and an edge portion positioned in a non-light-emitting region. In the forming the function layer, an overhanging portion including a portion having a thickness larger than a thickness of the body portion is formed in the edge portion.

A method for manufacturing a display device, according to a 17th aspect of the disclosure, includes, in the 16th aspect, forming, in the non-light-emitting region, a bank including an inner wall surface that is a surface on a side of the light-emitting region before the forming the function layer, and the overhanging portion is formed on the bank.

In a method for manufacturing a display device, according to an 18th aspect of the disclosure, in the 17th aspect, the bank is a table-shaped member further including an upper surface, and the overhanging portion is formed on the upper surface.

In a method for manufacturing a display device, according to a 19th aspect of the disclosure, in the 18th aspect, the bank includes an outer wall surface positioned outside the inner wall surface with respect to the light-emitting region, and the overhanging portion is formed at a boundary between the upper surface and the outer wall surface.

In a method for manufacturing a display device, according to a 20th aspect of the disclosure, in any of the 16th to 19th aspects, a maximum value of a thickness of the overhanging portion is twice or more the thickness of the body portion.

In a method for manufacturing a display device, according to a 21st aspect of the disclosure, in any of the 16th to 20th aspects, the forming the function layer includes forming a photoresist, exposing and developing the photoresist to form a template, applying the function layer, and lifting off the template to form the function layer in a predetermined region.

In a method for manufacturing a display device, according to a 22nd aspect of the disclosure, in the 21st aspect, the template is formed in a forward taper type, a reverse taper type, or a hook type, and the overhanging portion includes a transfer shape of the template of the forward taper type, a transfer shape of the template of the reverse taper type, or a transfer shape of the template of the hook type.

In a method for manufacturing a display device, according to a 23rd aspect of the disclosure, in any of the 16th to 22nd aspects, a width of the overhanging portion is larger than the thickness of the body portion.

In a method for manufacturing a display device, according to a 24th aspect of the disclosure, in any of the 16th to 23rd aspects, a width of the overhanging portion is larger than a maximum value of a thickness of the overhanging portion.

In a method for manufacturing a display device, according to a 25th aspect of the disclosure, in any of the 16th to 24th aspects, when an inclination angle of a side wall of the overhanging portion on an opposite side to the light-emitting region with respect to a normal direction of a surface on which the overhanging portion is formed is θ1 and an inclination angle of a side wall of the overhanging portion on a side of the light-emitting region with respect to the normal direction is θ2, θ1<θ2 is satisfied.

In a method for manufacturing a display device, according to a 26th aspect of the disclosure, in any of the 16th to 25th aspects, a plurality of the function layers are formed, and a plurality of light-emitting layers are individually formed as the plurality of function layers.

In a method for manufacturing a display device, according to a 27th aspect of the disclosure, in any of the 16th to 25th aspects, a plurality of the function layers are formed, and a plurality of carrier transport layers are individually formed as the plurality of function layers.

In a method for manufacturing a display device, according to a 28th aspect of the disclosure, in any of the 16th to 24th aspects, the function layer includes both a light-emitting layer and a carrier transport layer formed on the light-emitting layer, a plurality of the function layers are formed, and the light-emitting layer and the carrier transport layer are formed using a common template.

In a method for manufacturing a display device, according to a 29th aspect of the disclosure, in any of the 26th to 28th aspects, the plurality of function layers are formed, a first function layer, a second function layer, and a third function layer are formed in this order as the plurality of function layers, and the overhanging portion formed in the third function layer is overlapped with at least one of an end portion of the first function layer and an end portion of the second function layer.

In a method for manufacturing a display device, according to a 30th aspect of the disclosure, in the 29th aspect, the first function layer, the second function layer, and the third function layer are light-emitting layers configured to emit lights in different colors of red, green, and blue.

In a method for manufacturing a display device, according to a 31st aspect of the disclosure, in the 29th or 30th aspect, the third function layer including the overhanging portion overlapping the end portion of the first function layer and the end portion of the second function layer adjacent to each other is formed.

In a method for manufacturing a display device, according to a 32nd aspect of the disclosure, in the 29th or 30th aspect, the overhanging portion formed in the second function layer is overlapped with the end portion of the first function layer adjacent to the second function layer.

In a method for manufacturing a display device, according to a 33rd aspect of the disclosure, in any of the 26th to 28th aspects, a first function layer, a second function layer, and a third function layer are formed in this order as the plurality of function layers, and the edge portion formed in the first function layer and the edge portion formed in the third function layer are overlapped with each other.

In a method for manufacturing a display device, according to a 34th aspect of the disclosure, in any of the 26th to 33rd aspects, the plurality of function layers are each formed continuously in a line shape.

In a method for manufacturing a display device, according to a 35th aspect of the disclosure, in any of the 26th to 33rd aspects, the function layers are each continuously formed.

The disclosure is not limited to each of the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in the embodiments.

1. A display device comprising:
a function layer including a body portion positioned in a light-emitting region and an edge portion positioned in a non-light-emitting region; and
a bank formed in the non-light-emitting region and including an inner wall surface that is a surface on a side of the light-emitting region,
wherein the edge portion includes an overhanging portion including a portion having a thickness larger than a thickness of the body portion, and the overhanging portion is formed on the bank.

2. The display device according to claim 1,
wherein the bank is formed in a table shape including an upper surface.

3. The display device according to claim 2,
wherein the bank includes an outer wall surface positioned outside the inner wall surface with respect to the light-emitting region, and
the overhanging portion is formed at a boundary between the upper surface and the outer wall surface.

4. The display device according to claim 1,
wherein a maximum value of a thickness of the overhanging portion is twice or more the thickness of the body portion.

5. The display device according to claim 1,
wherein a width of the overhanging portion is larger than the thickness of the body portion.

6. The display device according to claim 1,
wherein a width of the overhanging portion is larger than a maximum value of a thickness of the overhanging portion.

7. The display device according to claim 1,
wherein when an inclination angle of a side wall of the overhanging portion on an opposite side to the light-emitting region with respect to a normal direction of a surface on which the overhanging portion is formed is θ1 and an inclination angle of a side wall of the overhanging portion on the side of the light-emitting region with respect to the normal direction is θ2, θ1<θ2 is satisfied.

8. The display device according to claim 1, comprising:
a plurality of the function layers,
wherein the function layers include a first function layer, a second function layer, and a third function layer.

9. The display device according to claim 8,
wherein the first function layer, the second function layer, and the third function layer are light-emitting layers configured to emit lights in different colors of red, green, and blue.

10. The display device according to claim 8,
wherein the overhanging portion of the third function layer overlaps at least one of an end portion of the first function layer and an end portion of the second function layer.

11. The display device according to claim 10,
wherein the overhanging portion of the third function layer overlaps the end portion of the first function layer and the end portion of the second function layer adjacent to each other.

12. The display device according to claim 8,
wherein the overhanging portion of the second function layer overlaps an end portion of the first function layer adjacent to the second function layer.

13. The display device according to claim 1, comprising:
a plurality of the function layers,
wherein the function layers are carrier transport layers, and
the plurality of function layers are formed for each pixel.

14. The display device according to claim 8,
wherein the plurality of function layers are each formed in a line shape.

15. The display device according to claim 8,
wherein the function layers are continuously formed.

16. A method for manufacturing a display device, the method comprising:
forming a function layer including a body portion positioned in a light-emitting region and an edge portion positioned in a non-light-emitting region,
wherein in the forming the function layer, an overhanging portion including a portion having a thickness larger than a thickness of the body portion is formed in the edge portion.

17. (canceled)

18. (canceled)

19. The method for manufacturing a display device, according to claim 16, the method comprising:
forming, in the non-light-emitting region, a bank including an inner wall surface that is a surface on a side of the light-emitting region before the forming the function layer,
wherein the overhanging portion is formed on the bank,
the bank is a table-shaped member further including an upper surface,
the overhanging portion is formed on the upper surface,
the bank includes an outer wall surface positioned outside the inner wall surface with respect to the light-emitting region, and
the overhanging portion is formed at a boundary between the upper surface and the outer wall surface.

20-24. (canceled)

25. The method for manufacturing a display device, according to claim 16,
wherein when an inclination angle of a side wall of the overhanging portion on an opposite side to the light-emitting region with respect to a normal direction of a surface on which the overhanging portion is formed is θ1 and an inclination angle of a side wall of the overhanging portion on a side of the light-emitting region with respect to the normal direction is θ2, θ1<θ2 is satisfied.

26. The method for manufacturing a display device, according to claim 16,
wherein a plurality of the function layers are formed, and
a plurality of light-emitting layers are individually formed as the plurality of function layers.

27. (canceled)

28. The method for manufacturing a display device, according to claim 16,
wherein the function layer includes both a light-emitting layer and a carrier transport layer formed on the light-emitting layer,
a plurality of the function layers are formed, and
the light-emitting layer and the carrier transport layer are formed using a common template.

29-35. (canceled)
